(19) United States
(12) Patent Application Publication
(10) Pub. No.: US 2009/0166619 A1
(43) Pub. Date: Jul. 2, 2009

(54) TEST PATTERN OF SEMICONDUCTOR DEVICE AND MANUFACTURING METHOD THEREOF

(75) Inventor: Chan Ho PARK, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/262,005

(22) Filed: Oct. 30, 2008

(30) Foreign Application Priority Data
Dec. 26, 2007 (KR) 10-2007-0136999

(51) Int. Cl. H01L 23/58; H01L 21/76

(52) U.S. Cl. 257/48; 438/401; 257/E23.001; 257/E21.54

(57) ABSTRACT

A method of manufacturing a test pattern for a semiconductor device includes the steps of forming, on a semiconductor substrate, a moat mask pattern including plural moat lines patterned in a comb-shape and etching a portion of the semiconductor substrate exposed by the moat mask pattern, to form a trench. The method further includes gap-filling the trench with an insulation material to form a field separator, planarizing the semiconductor substrate having the field separator formed thereon, and forming a poly comb pattern on the planarized semiconductor substrate. The poly comb pattern is formed such that the moat lines are arranged between lines of the poly comb pattern.

### CROSS-REFERENCE TO RELATED APPLICATION

This application claims priority to Korean Application No. 10-2007-0136999, filed on Dec. 26, 2007, which is incorporated herein by reference in its entirety.

### BACKGROUND

1. Field of the Invention

Embodiments of the present invention generally relate to a test pattern of a semiconductor device.

2. Description of Related Art

To conduct an interconnect parasitic capacitance analysis, the thickness of any inter metal dielectric (IMD) including a field oxide is an important parameter for determining a variation of capacitance in resistance-capacitance (RC) delay models. For example, a poly-to-substrate parasitic capacitance is determined in a dielectric based structure (defined by a poly interconnect and a substrate) to form a dielectric feature, such as a shallow trench isolation (STI). In general, the capacitance of a poly-to-substrate structure can be determined by forming a poly comb pattern on a field separator, measuring a total capacitance of the pattern, and dividing the total capacitance by the number of lines of the poly comb. The measured capacitance from the poly comb pattern is used for obtaining the thickness of the field separator, and the separator thickness so measured is then used for setting up a worst-case interconnect model variation. This procedure can also be adopted as a process monitoring technique, e.g., to evaluate uniformity of a global planarization in a wafer or a die on which a chemical mechanical polishing (CMP) process has been performed.

FIG. 1A is a plan view of a test pattern used to determine the thickness of a field separator between a polyelectrode and a substrate by measuring a capacitance of a poly line (or plate)-to-substrate structure, and FIG. 1B is a cross-sectional view of the test pattern.

In FIGS. 1A and 1B, reference numeral 20 denotes polyelectrode lines that form a capacitor, reference numeral 10 denotes a power line connecting the respective polyelectrode lines 20, reference numeral 30 denotes a field separator, and reference numeral 40 denotes a substrate.

In general, when a capacitance is measured by using the test pattern with the structure illustrated in FIG. 1A or FIG. 1B, a poly capacitor having a relatively large area is required because of a test resolution limit of measurement equipment (e.g., LCR meter). For example, several tens to several hundreds of polyelectrode lines may be required, each having a length of several tens to several hundreds micrometers. Moreover, a large field separator, e.g., as large as the poly capacitor, is disposed underneath the poly capacitor.

The width and spacing of polyelectrode lines are based on the design rules of a respective semiconductor manufacturing process technique. For example, a semiconductor manufacturing process technique may use a DUT (Device Under Test) with a minimum width and a minimum spacing, and several DUTs with a minimum spacing and an enlarged width.

As discussed above, because of the resolution limit of capacitance measuring equipment, the number of polyelectrode lines should be increased to have a large enough capacitance value to be reliably measured. However, the increase in the total number of polyelectrode lines entails a corresponding increase in size and eventually the enlargement of a field separator area underneath the polyelectrode lines.

In addition, if the field separator is formed by an oxide CMP technique used for making STI, a dishing phenomenon (see 60 in FIG. 1B) becomes more pronounced as the area of the field separator gets broader. As shown in FIG. 1B, distances between the respective polyelectrode lines and the substrate differ from one another due to the dishing phenomenon 60. In other words, because of the dishing phenomenon, the polyelectrode line at the center and the polyelectrode lines at the outermost sides form capacitors of different heights from the substrate. This results in the formation of a non-uniform poly-to-substrate capacitor.

### SUMMARY OF SOME EXAMPLE EMBODIMENTS

In general, example embodiments of the invention relate to a test pattern for measuring a poly-to-substrate capacitance that overcomes factors that cause non-uniform field separators, such as a dishing phenomenon resulting from a CMP process.

Other example embodiments relate to a manufacturing method of the improved test pattern to determine an interconnect parameter more accurately.

In accordance with one embodiment, there is provided a method of manufacturing a test pattern for a semiconductor device, the method including the steps of forming, on a semiconductor substrate, a moat mask pattern having plural moat lines patterned in a comb-shape. The method further includes etching a portion of the semiconductor substrate exposed by the moat mask pattern to form a trench and gap-filling the trench with an insulation material to form a field separator. The semiconductor substrate having the field separator formed thereon is then planarized and a poly comb pattern is formed on the planarized semiconductor substrate. The poly comb pattern is formed such that the moat lines are arranged between lines of the poly comb pattern.

In accordance with another embodiment, there is provided a test pattern for a semiconductor device, including a semiconductor substrate and a poly comb pattern including plural polyelectrode lines patterned in a comb shape to form a capacitor with the semiconductor substrate and a power line for connecting the polyelectrode lines. The test pattern also includes a field separator formed between the semiconductor substrate and the polyelectrode lines, and plural moat lines patterned in a comb shape between the polyelectrode lines.

In accordance with another embodiment, there is provided a method of manufacturing a test pattern for a semiconductor device, the method including the steps of forming, on a metal film, a moat mask pattern including plural moat lines patterned in a comb-shape, etching a portion of the metal film exposed by the moat mask pattern to form a trench, gap-filling the trench with an insulation material to form a field separator, planarizing the metal film having the field separator formed thereon, and forming a poly comb pattern on the planarized metal film. The poly comb pattern may be formed such that the moat lines are arranged between lines of the poly comb pattern.

In accordance with another embodiment, there is provided a test pattern for a semiconductor device, including a metal film, a poly comb pattern including plural polyelectrode lines patterned in a comb shape to form a capacitor with the metal film, and a power line for connecting the polyelectrode lines, a field separator formed between the metal film and the polyelectrode lines, and plural moat lines patterned in a comb shape between the polyelectrode lines.

In accordance with example embodiments described herein, a test pattern is provided, which removes factors that cause a non-uniform field separator, such as the dishing phenomenon resulting from a CMP process in a poly line-to-substrate capacitor, poly plate-to-substrate capacitor, or poly-to-metal capacitor. Therefore, an accurate poly-to-substrate capacitance can be determined and used for an interconnect characterization.

A capacitance determined in such a way can be expressed as the thickness of a field separator, which can be used for evaluating the global uniformity in the field separator thickness within a given tolerance.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

Aspects of example embodiments of the invention will become apparent from the following description of example embodiments, given in conjunction with the accompanying drawings, in which:

FIG. 1A shows a plan view of a conventional semiconductor device test pattern, and FIG. 1B shows a cross-sectional view of the test pattern;

FIG. 2A shows a plan view of a semiconductor device test pattern in accordance with an example embodiment of the present invention, and FIG. 2B shows a cross-sectional view of the test pattern;

FIG. 3 illustrates a flowchart for explaining a manufacturing method of the test pattern in accordance with an embodiment of the present invention;

FIGS. 4A to 4C present plural DUTs for measuring a capacitance by using the test pattern in accordance with an embodiment of the present invention;

FIG. 5 shows a capacitor level structure of the test pattern in accordance with an embodiment of the present invention; and

FIG. 6 depicts a graph showing capacitance characteristics of the DUTs depicted in FIGS. 4A to 4C.

### DETAILED DESCRIPTION OF SOME EXAMPLE EMBODIMENTS

In the following detailed description of the embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

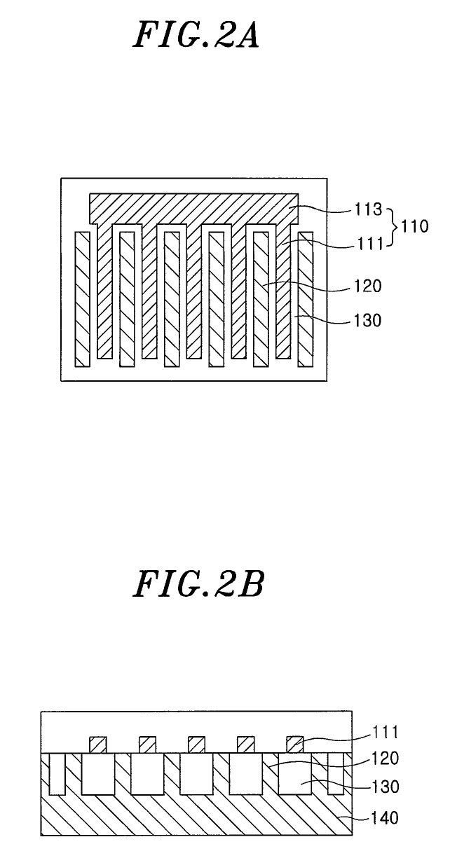

FIG. 2A shows a plan view of a test pattern in accordance with an example embodiment. The test pattern may be used to determine the thickness of a field separator between a polyelectrode and a substrate by measuring a capacitance of a poly line (or plate)-to-substrate structure, and FIG. 2B shows a cross-sectional view of the test pattern.

Referring to FIGS. 2A and 2B, an example embodiment of a test pattern may include a poly comb pattern 110 having plural polyelectrode lines 111 patterned in a comb shape to form a capacitor and a power line 113 for connecting the polyelectrode lines 111, together with a substrate 140. The test pattern may also include a field separator 130, between the substrate 140 and the polyelectrode lines 111, and plural moat lines 120 patterned in a comb shape between the polyelectrode lines 111.

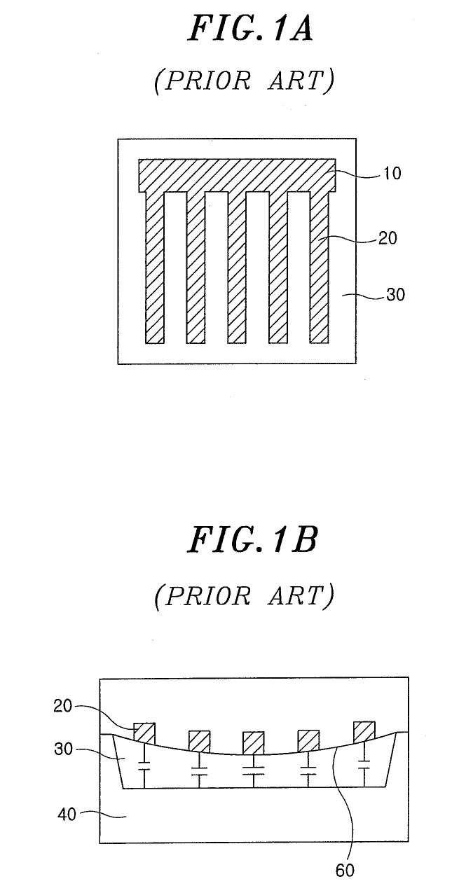

As indicated by a comparison between the cross-sectional view of the conventional test pattern (see FIG. 1B) and the cross-sectional view of the test pattern formed in accordance with an example embodiment of the present invention (see FIG. 2B), the dishing phenomenon of the field separator is observed only in the prior art, not in the field separator 130 formed in accordance with an embodiment of the present invention. This is because the test pattern of FIG. 2B has the moat lines 120 disposed between the polyelectrode lines 111. Therefore, the field separator 130 is not formed broadly in proportion to the broad size of the poly comb pattern 110. Instead, the area of the field separator 130 is rather limited by the moat lines 120. As a result, no dishing phenomenon due to the CMP process occurs.

When the dishing phenomenon of the field separator 130 does not occur, the thickness of the field separator 130 is uniform with respect to each of the polyelectrode lines 111 within the poly comb pattern 110, and a uniform capacitance is formed. Therefore, an accurate thickness of the field separator can be obtained because an accurate poly-to-substrate capacitance can be determined.

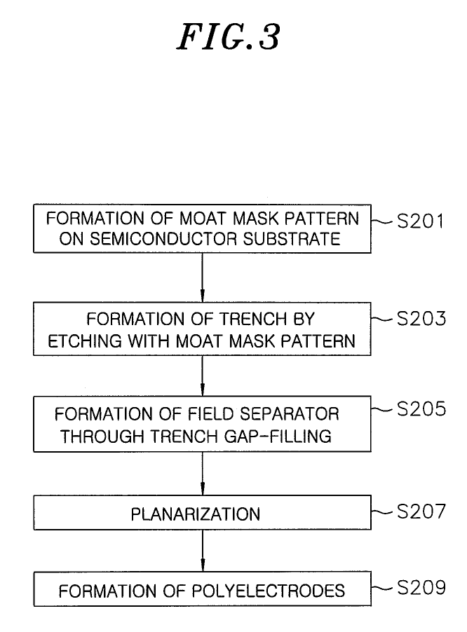

FIG. 3 illustrates a flowchart for explaining a manufacturing method of the test pattern in accordance with an example embodiment of the present invention.

Referring to FIG. 3, in step S201, a moat mask pattern having an open region for forming a field separator 130 on a semiconductor substrate 140 is first formed. Since moat lines 120 are formed by the moat mask pattern, the moat mask pattern may have the same shape as that of reference numeral 120 in FIG. 2A. That is, plural moat lines having a comb pattern may be arranged between areas where the polyelectrode lines 111 are to be formed. Moreover, the moat mask pattern may be formed by laminating an oxide film and a nitride film over the semiconductor substrate 140 to form a hard mask insulation film and then patterning the insulation film by photolithography or the like to get a hard mask pattern.

Next, in step S203, a portion of the semiconductor substrate 140 exposed by the moat mask pattern may be dry etched to a predetermined thickness to form a trench.

In a following step S205, a trench filling material (which is an insulation material) is deposited, by atmospheric pressure chemical vapor deposition (APCVD) for example, on the front face of the semiconductor substrate 140 having the trench, such that the trench is gap-filled to form a field separator 130.

Subsequently, in step S207 a planarization process, such as the CMP process, may be carried out to remove any excess portions of the field separator 130 existing outside of the trench region, thereby planarizing the semiconductor substrate 140.

Finally, in step S209, a poly layer for the polyelectrodes may be formed and then patterned by photolithography, or the like, to form the target poly comb pattern 110.

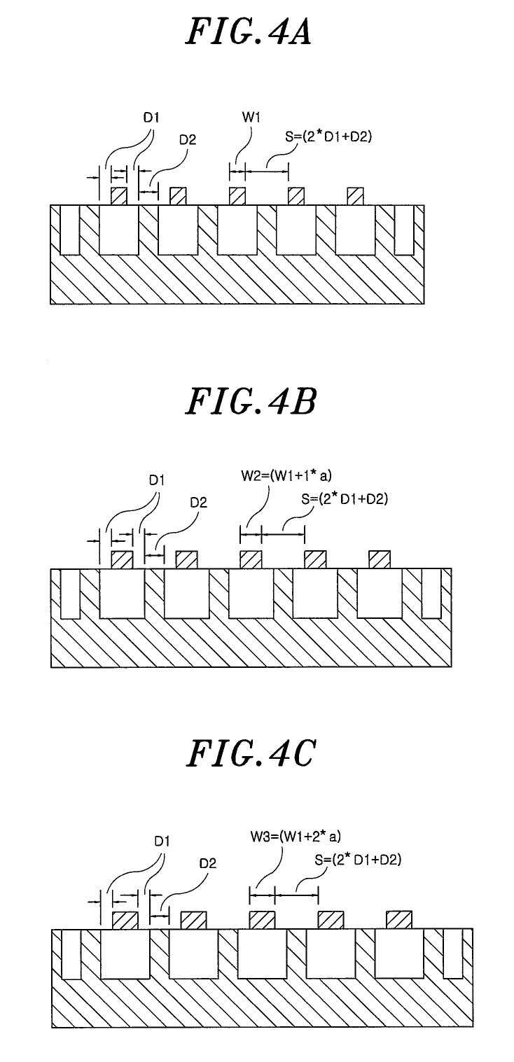

In order to measure the thickness of a field separator, several poly-to-substrate capacitance measurements may be made in DUTs having different polyelectrode line widths. For example, a DUT with a uniform width and a uniform spacing of polyelectrode lines may first be manufactured, followed by preparation of plural DUTs with gradually increasing polyelectrode line widths. For example, the polyelectrode line widths may increase by a fixed amount but the spacing between the polyelectrode lines may be consistent in each DUT. As can be seen from FIGS. 4A to 4C showing such DUTs, a spacing S between the polyelectrode lines stays the same, but a width W1, W2, and W3 of the polyelectrode lines in each DUT is gradually increased.

FIG. 5 shows that a capacitance formed by polyelectrode lines includes an intrinsic capacitance (Cᵢ) 303, determined by the width of the polyelectrode line, and fringe capacitances (C_{f}) 301, determined by the spacing between the polyelectrode lines.

Because the poly comb patterns in FIGS. 4A to 4C each have the same spacing and vary only by their line widths, the value of the C_{f} 301 is the same for each.

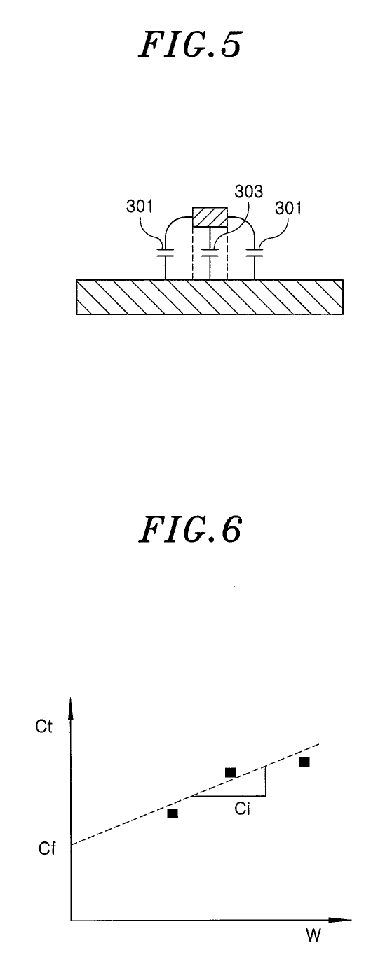

Because the C_{f} 301 is the same for the capacitors having different widths but the same spacing, the thickness of a field separator in a poly-to-substrate structure can be obtained based on Cᵢ (derived from the graph in FIG. 6) and Equation (1) below, which relates an oxide thickness (Tₒₓ) with Cᵢ.

Tₒₓ=εₒₓ/Cᵢ Eq. (1)

wherein εₒₓ is the dielectric constant of a dielectric.

FIG. 6 shows a graph, in which the Y-intercept is denoted C_{f} and the slope of a fitting line corresponds to Cᵢ. Both C_{f} and Cᵢ are obtained by fitting Cₜ (Cᵢₙₜₑᵣ_{_{—}}_{down}), which denotes a capacitance per unit length of a poly-to-substrate capacitor measured, and which corresponds to a sum of one Cᵢ 303 and two C_{f} 301. The fitting line is fit to capacitance measurements made in at least three DUTs, each varying in the width of their polyelectrode lines.

Although an embodiment has been described with respect to a test pattern in a poly line-to-substrate capacitor structure, the description above can also be applied to a poly-to-metal capacitor structure because the influence of dishing phenomenon in a field separator is the same for a poly-to-metal capacitor structure. In other words, the occurrence of the dishing phenomenon of the field separator can be prevented by forming a comb-shaped pattern of plural moat lines between a comb-shaped pattern of polyelectrode lines that form the poly-to-metal capacitor.

Moreover, the test pattern described above can be applied to a poly plate-to-substrate capacitor used for interconnect characterization. For example, the plate may be split into a comb pattern as in the above-described embodiment. That is to say, when a poly plate forming a poly plate-to-substrate capacitor is split into polyelectrode lines with a comb-shaped pattern, it is possible to avoid the dishing phenomenon of the field separator by forming plural moat lines with a comb-shaped pattern between the split polyelectrode lines.

While the invention has been shown and described with respect to example embodiments, it will be understood by those skilled in the art that various changes and modification may be made without departing from the scope of the invention as defined in the following claims.

What is claimed is:

1. A method of manufacturing a test pattern for a semiconductor device, the method comprising the steps of:
forming, on a semiconductor substrate, a moat mask pattern including a plurality of moat lines patterned in a comb-shape;
etching a portion of the semiconductor substrate exposed by the moat mask pattern to form a trench;
gap-filling the trench with an insulation material to form a field separator;
planarizing the semiconductor substrate having the field separator formed thereon; and
forming a poly comb pattern on the planarized semiconductor substrate,
wherein the moat lines are arranged between lines of the poly comb pattern.

2. The method of claim 1, wherein the moat mask pattern is a hard mask type pattern obtained by forming and patterning a hard mask insulation film above the semiconductor substrate.

3. A test pattern for a semiconductor device, comprising:
a semiconductor substrate;
a poly comb pattern including plural polyelectrode lines patterned in a comb shape to form a capacitor with the semiconductor substrate, and a power line for connecting the polyelectrode lines;
a field separator formed between the semiconductor substrate and the polyelectrode lines; and
a plurality of moat lines patterned in a comb shape between the polyelectrode lines.

4. The test pattern of claim 3, the polyelectrode lines are manufactured such that the polyelectrode lines have the same spacing but different widths.

5. A method of manufacturing a test pattern for a semiconductor device, the method comprising the steps of:
forming, on a metal film, a moat mask pattern including a plurality of moat lines patterned in a comb-shape;
etching a portion of the exposed metal film exposed by the moat mask pattern to form a trench;
forming a field separator;
planarizing the metal film having the field separator formed thereon; and
forming a poly comb pattern on the planarized metal film,
wherein the moat lines are arranged between lines of the poly comb pattern.

6. The method of claim 5, wherein the moat mask pattern is a hard mask type pattern obtained by forming and patterning a hard mask insulation film above the metal film.

7. A test pattern for a semiconductor device, comprising:
a metal film;
a poly comb pattern including plural polyelectrode lines patterned in a comb shape to form a capacitor with the metal film, and a power line for connecting the polyelectrode lines;
a field separator formed between the metal film and the polyelectrode lines; and
plural moat lines patterned in a comb shape between the polyelectrode lines.

8. The test pattern of claim 7, the polyelectrode lines are manufactured in a manner that the polyelectrode lines have the same spacing but different widths.
